(19) United States
(12) Patent Application Publication
(10) Pub. No.: US 2013/0042808 A1
(43) Pub. Date: Feb. 21, 2013

(54) FILM CRACK DETECTION APPARATUS AND FILM FORMING APPARATUS

(71) Applicant: Yudo SUGAWARA, Oshu-shi (JP)

(72) Inventor: Yudo SUGAWARA, Oshu-shi (JP)

(73) Assignee: TOKYO ELECTRON LIMITED, Tokyo (JP)

(21) Appl. No.: 13/585,504

(22) Filed: Aug. 14, 2012

(30) Foreign Application Priority Data
Aug. 16, 2011 (JP) 2011-177991

(51) Int. Cl. G01N 29/04; H01L 21/205; C23C 16/52

(52) U.S. Cl. 118/712; 73/584

(57) ABSTRACT

A film crack detection apparatus for performing a film crack detection operation, which is mounted to a film forming apparatus having a processing vessel for receiving an object to be processed and forming a thin film on a surface of the object to be processed, includes an elastic wave detection unit mounted to the film forming apparatus to detect an elastic wave, and a determination unit to determine whether performing a cleaning process of the processing vessel is necessary based on a detection result of the elastic wave detection unit.

### CROSS-REFERENCE TO RELATED APPLICATION

This application claims the benefit of Japanese Patent Application No. 2011-177991, filed on Aug. 16, 2011, in the Japan Patent Office, the disclosure of which is incorporated herein in its entirety by reference

### TECHNICAL FIELD

The present disclosure relates to a film forming apparatus which forms a thin film on a semiconductor wafer and a film crack detection apparatus mounted to the film forming apparatus.

### BACKGROUND

In general, in order to manufacture a semiconductor device such as a semiconductor integrated circuit, a semiconductor wafer such as a silicon substrate, is repeatedly subjected to various processes, such as a film forming process, an etching process, an oxidation process, a diffusion process, etc. For example, in a batch-type film forming process, a plurality of semiconductor wafers supported by a wafer boat are accommodated in a vertically extending processing vessel made of quartz. A thin film is formed by introducing a film forming gas into the processing vessel while heating the semiconductor wafers at a predetermined temperature under a vacuum atmosphere.

After the aforementioned film forming process is repeatedly performed, an unnecessary film is increasingly attached and accumulated on an inner surface of the processing vessel. Peeling-off of the unnecessary film generates particles causing a reduction of the yield rate. Therefore, conventionally, for example, a cumulative value of the thicknesses of the films formed with respect to the wafers has been managed, whereby removing the unnecessary film from the inner surface of the processing vessel by performing a cleaning process on a regular or irregular basis before film detachment of the unnecessary film occurs.

However, in the aforementioned conventional cleaning process, if an estimate of the cumulative thickness value for the start of the cleaning process is set too high, a problem may result in which the cleaning process happens too late resulting in a great deal of particles, thereby causing a sharp reduction of the yield rate. On the other hand, if the estimate of the cumulative thickness value is set too low, the cleaning process is performed even though the occurrence of particles is greatly less than the permissible amount. As a result, a problem may result in that the frequency of the cleaning process increases, thereby reducing the throughput or accelerating wear of the processing vessel.

### SUMMARY

The present disclosure provides some embodiments of a film crack detection apparatus and a film forming apparatus, which can recognize the possibility of the occurrence of particles in real time by detecting a film crack of an unnecessary film attached to an inner wall of a processing vessel.

According to one embodiment of the present disclosure, provided is a film crack detection apparatus, mounted to a film forming apparatus, for performing a film crack detection operation, the film forming apparatus having a processing vessel for receiving an object to be processed and forming a thin film on a surface of the object to be processed, including an elastic wave detection unit mounted to the film forming apparatus to detect an elastic wave, and a determination unit to determine whether performing a cleaning process of the processing vessel is necessary based on a detection result of the elastic wave detection unit.

According to another embodiment of the present disclosure, provided is a film forming apparatus for forming a thin film on an object to be processed, including a processing vessel to receive the object to be processed, a holding device to hold the object to be processed, a heater to heat the object to be processed, a gas supply unit to supply a gas into the processing vessel, an exhaust system to exhaust an atmosphere within the processing vessel, the film crack detection apparatus of the aforementioned embodiment, and a controller to control the entire operation of the film forming apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view of a film forming apparatus to which a film crack detection apparatus is mounted according to one embodiment of the present disclosure.

FIG. 2 is a partially exploded sectional view showing mounting of the film crack detection apparatus.

FIG. 3 is a block diagram showing a determination unit of the film crack detection apparatus.

FIG. 4 is a partial view showing a first modified embodiment of the film crack detection apparatus of the present disclosure.

FIGS. 5A and 5B are graphs showing a relationship between a load and an occurrence of a crack.

FIGS. 6A and 6B are graphs showing a wave pattern at a point where the strength of an elastic wave is highest.

FIG. 7 is a block diagram showing a part of a second modified embodiment of the film crack detection apparatus according to the present disclosure.

FIGS. 8A to 8C are graphs showing an analysis of the occurrence of micro cracks based on the data obtained from FIGS. 5A and 5B.

FIGS. 9A to 9D are graphs showing relationships between an AE wave and a frequency by group.

FIG. 10 is a partially exploded sectional view showing a modified embodiment of the mounting of an elastic wave detection device.

FIG. 11 is a partially exploded sectional view showing another modified embodiment of the elastic wave detection device.

### DETAILED DESCRIPTION

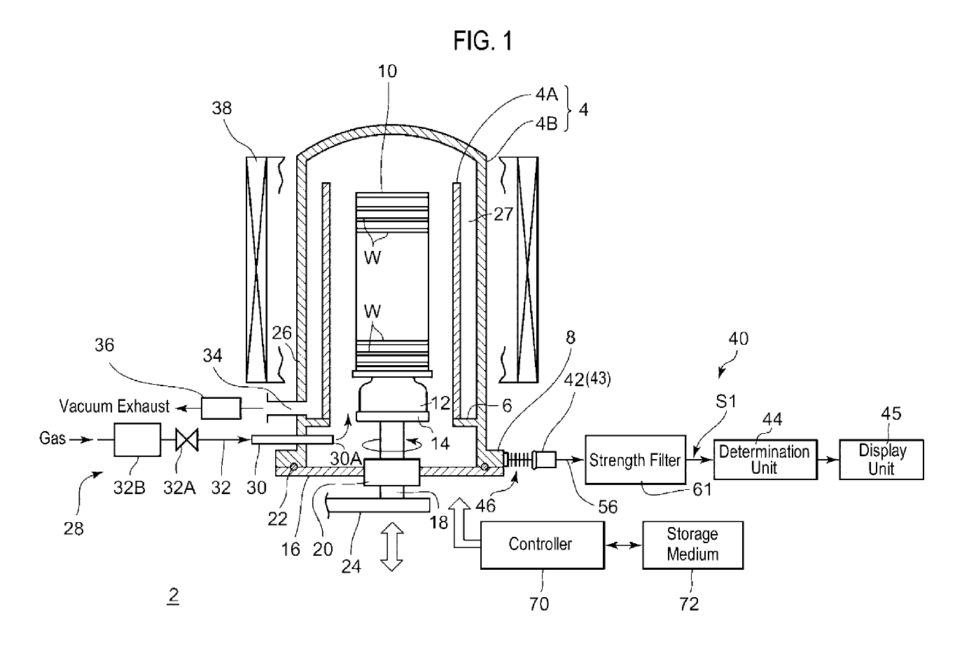

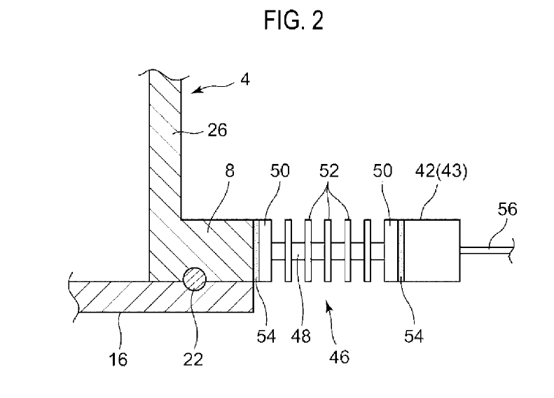

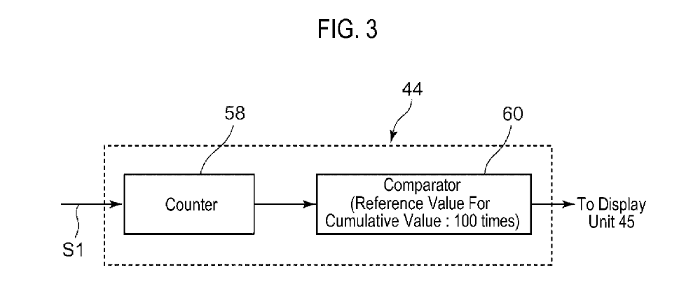

An embodiment of a film crack detection apparatus and a film forming apparatus according to the present disclosure will now be described in detail with reference to the drawings. FIG. 1 is a longitudinal sectional view of a film forming apparatus 2 to which a film crack detection apparatus 40 is mounted according to one embodiment of the present disclosure. FIG. 2 is a partially exploded sectional view showing mounting of the film crack detection apparatus 40. FIG. 3 is a block diagram showing a determination unit 44 of the film crack detection apparatus 40.

As shown in the figures, the film forming apparatus 2 includes a cylindrical processing vessel 4 with an opened lower end and a ceiling. The processing vessel 4 is made of, for example, quartz. The processing vessel 4 includes a cylindrical inner vessel 4A and an outer vessel 4B having the ceiling. The outer vessel 4B is outwardly spaced from the inner vessel 4A by a predetermined distance, while being disposed concentrically to the inner vessel 4A. The inner vessel 4A is supported on a support ring 6 formed on an inner wall at a lower portion of the outer vessel 4B. A lower end of the processing vessel 4, i.e., a lower end of the outer vessel 4B, is opened. The lower end has a flange 8 in a thick ring shape. It may be possible, for example, to connect a cylindrical manifold made of stainless steel to the lower end opening.

A wafer boat 10, as a holding device, made of quartz, in which a plurality of semiconductor wafers W, as an object to be processed, are stacked, can vertically move up and down from a lower side of the lower end opening of the processing vessel 4 such that it can be fit into the lower end opening of the processing vessel 4. In this embodiment, rods (not shown) of the wafer boat 10 are configured to support, for example, about 50 to 150 wafers W having a diameter of 300 mm stacked at approximately equal pitches.

The wafer boat 10 is positioned on a table 14 by a heat insulation tube 12 made of quartz. The table 14 is supported on a rotating shaft 18 penetrating a lid member 16 which is made of, e.g., stainless steel, and serves to open and close the lower end opening of the processing vessel 4. A magnetic fluid seal 20 is installed at a penetrating portion of the rotating shaft 18 to air-tightly seal and rotatably support the rotating shaft 18. A sealing member 22 including, e.g., an O-ring, is installed at a periphery of the lid member 16 and the lower end portion of the processing vessel 4 to maintain air-tightness of the processing vessel 4.

The rotating shaft 18 is mounted on a front end of an arm 24 supported by an elevating mechanism (not shown) such as a boat elevator. The wafer boat 10 and the lid member 16 can move up and down integrally such that they can be fit into the processing vessel 4. It may be possible to fixedly mount the table 14 onto the lid member 16 such that a process of the wafers W can be performed without rotating the wafer boat 10.

A gas supply unit 28 which supplies a necessary gas, such as a film forming gas, into the processing vessel 4 is installed at a side wall 26 in a lower portion of the processing vessel 4. Specifically, the gas supply unit 28 has a gas nozzle 30 of a quartz tube extending through the side wall 26 in the lower portion of the processing vessel 4. The gas nozzle 30 is configured to inject gas through a gas injection hole 30A provided at a front end thereof. A gas passage 32 is connected to the gas nozzle 30. The gas passage 32 is provided with an opening and closing valve 32A and a flow controller 32B, such as a mass flow controller, such that gas can be supplied while the flow rate thereof is controlled.

Although FIG. 1 only shows one gas supply unit 28, a plurality of gas supply units having the same configuration as that of the gas supply unit 28 are installed as many as the number of kinds of gases to be used. For example, in the case of forming a silicon nitride film, dichlorosilane as a silane-containing gas, ammonia as a nitriding gas, and nitrogen gas as a purge gas are used.

An exhaust port 34 is formed in the side wall 26 in the lower portion of the processing vessel 4 at a portion corresponding to a gap 27 between the inner vessel 4A and the outer vessel 4B. An exhaust system 36 in which a pressure control valve or a vacuum pump (not shown) is installed is connected to the exhaust port 34 such that an atmosphere within the processing vessel 4 is evacuated and maintained at a predetermined pressure. Thus, a gas introduced from the gas nozzle 30 flows in such a way that it firstly goes up in the inner vessel 4A, turns its direction toward the ceiling and then goes down along the gap 27 between the inner vessel 4A and the outer vessel 4B to be exhausted from the exhaust port 34.

A cylindrical heater 38, which heats the processing vessel 4 and the wafers W therein, is installed so as to surround an outer periphery of the processing vessel 4. The film crack detection apparatus 40 according to the present disclosure is installed at the lower end portion of the processing vessel 4. The film crack detection apparatus 40 includes an elastic wave detection unit 42 mounted to the film forming apparatus 2 to detect an elastic wave, and a determination unit 44 which determines whether a cleaning process of the processing vessel 4 is necessary based on a result detected by the elastic wave detection unit 42. A display unit 45 is connected to the determination unit 44 for displaying a determination result thereof.

Specifically, the elastic wave detection unit 42 is mounted to the flange 8 in the lower end portion of the processing vessel 4. Herein, an elastic wave indicates a wave occurring when material emits strain energy stored therein due to deforming or a crack occurring in the material. It is possible to use an AE (Acoustic Emission) sensor 43 as the elastic wave detection unit 42. As shown in FIG. 2, since the flange 8 experiences a high temperature inherently, the AE sensor 43 is joined to the flange 8 via a waveguide member 46.

The waveguide member 46 is, as a whole, made of a metal such as aluminum or stainless steel. Specifically, the waveguide member 46 includes a rod 48 having a length of several centimeters for ease of transmission of the elastic wave and a pair of disc shaped mounting plates 50 at both ends thereof. A plurality of radiating fins 52 disposed at predetermined intervals therebetween are mounted to the rod 48, thereby cooling the AE sensor 43 to its heat-resistant temperature or a temperature under thereof.

Close-contact members 54, which facilitate the transmission of the elastic wave, are interposed between the mounting plate 50 and the flange 8, and between the mounting plate 50 and the AE sensor 43. It is possible to use a liquid glass, silicon grease, or a soft metal plate such as a copper plate or a gold plate as the close-contact members 54. If the heat-resistant property of the AE sensor 43 is high, it is possible to mount the AE sensor 43 directly to the flange 8 without using the waveguide member 46. The AE sensor 43 is equipped with a piezoelectric element therein, e.g., a PZT (lead zirconate titanate), to have a frequency band of a few kHz to dozens of kHz as its oscillation frequency band. It is possible to use, for example, “AE144A” (manufactured by Vallen-Systeme Co.) as the AE sensor 43.

The elastic wave detection unit 42 is connected to the determination unit 44 via a signal line 56 in order to transmit a detection result. A strength filter 61, which outputs signals having a strength equal to or greater than a predetermined signal strength as an elastic wave detection signal, is disposed in the middle of the signal line 56 so as to cut a noise component. Herein, the strength filter 61 is configured to cut signals lower than a predetermined gain, for example, signals lower than 40 dB as the noise. It is possible to use, e.g., a high speed AE measurement system “AMSY-6” (manufactured by Vallen-Systeme Co.) as the strength filter 61.

As shown in FIG. 3, the determination unit 44 includes a counter 58 which obtains the number of detections of the elastic wave detection signal, which may be implemented by, e.g., a computer, and a comparator 60 which compares the output from the counter 58 with a predetermined reference value. The counter 58 obtains the number of occurrences of film cracks by counting a pulse of a pulse wave of a needle end shape, wherein the pulse wave of a needle end shape is output from the strength filter 61 as the elastic wave detection signal S1 when a film crack occurs.

In this case, as a first type of counter, the counter 58 is configured to obtain, for example, a cumulative value after the previous cleaning process of the processing vessel 4 finishes. That is, once the cleaning process is performed, an unnecessary film attached on an inner wall surface of the processing vessel 4 is removed. Therefore, the detection is performed only with respect to film cracks occurring after the previous cleaning process and the cumulative value is obtained by adding the number of detections. The counter 58 is configured to output the cumulative value to the comparator 60. The counting operation, i.e., the film crack detection operation, can be performed not only during the process of forming the thin film, but also during the process of increasing the temperature of the processing vessel 4 just before the film forming process, and during the process of decreasing the temperature of the processing vessel 4 after the film forming process.

The comparator 60 is configured to have a threshold obtained through an experiment set as a reference value. When the cumulative value sent from the previous step reaches the reference value, the comparator 60 determines that there is a need for the cleaning process. In this case, the reference value for the cumulative value may be set, for example, 100. In other words, when a film crack is detected 100 times, the comparator 60 recognizes that there is a need for the cleaning process.

Control of an entire operation of the film forming apparatus 2, for example, start and stop of a gas supply, setting of a processing temperature or a processing pressure, and control of an operation of the film crack detection apparatus 40, is performed by a controller 70 implemented by, for example, a computer. The controller 70 has a storage medium 72 which stores a computer readable program for control of the start or the stop of respective gas supply, on/off control of the high frequency, and control of an operation of the entire apparatus. Examples of the storage medium 72 include a flexible disc, a CD (Compact Disc), a hard disc, a flash memory, or a DVD.

Next, a film forming method by using the film forming apparatus 2 with the aforementioned configurations will be described with one example of forming a silicon nitride film (SiN). As shown in FIG. 1, the wafer boat 10, on which, e.g., 50 to 150 wafers W of a room temperature having a diameter of 300 mm are stacked, is loaded into the processing vessel 4 of a predetermined temperature by being raised from the lower portion. The vessel is air-tightly sealed by closing the lower end opening of the processing vessel 4 with the lid member 16.

While the processing pressure is maintained within the processing vessel 4 after lowering the pressure within the processing vessel 4 through evacuation, the processing temperatures of the processing vessel 4 and the wafers W are also maintained after raising the temperatures of the processing vessel 4 and the wafers W, wherein the temperatures are raised by increasing the electric power supplied to the heater 38. The gas supply unit 28 (or a plurality of units) supplies alternately and intermittently, for example, silane-containing gas and NH₃ gas, respectively. In this manner, the silicon nitrate film (SiN) is formed on the surfaces of the wafers W supported by the rotating wafer boat 10.

When the film forming process is finished, the temperatures of the processing vessel 4 and the wafers W are decreased to a safety temperature, for example, 300 to 400 degrees C., after stopping the supply of gas. When the temperatures of the processing vessel 4 and the wafers W reach the safety temperature, the processed wafers W are lowered to the lower portion of the processing vessel 4 for an unloading procedure, thereby being discharged from the processing vessel 4. The film crack detection operation is performed by the film crack detection apparatus 40 according to the present disclosure during the aforementioned operations. That is, the film crack detection operation can be performed during increasing the temperature of the processing vessel 4 before forming the thin film, during forming the thin film, and during decreasing the temperature of the processing vessel 4 after forming the thin film.

As described above, in the film forming process of the thin film, unnecessary film causing particles is adhered onto all surfaces of the structures within the vessel such as the surfaces of the wafers W, the inner wall surface of the processing vessel 4, and a surface of the gas nozzle 30, thereby accumulating by an increase of the number of film forming processes performed. When the unnecessary film becomes a certain thickness, a film crack occurs in the unnecessary film causing particles. Particularly, a film crack may be easily generated by a heat shock when increasing or decreasing the temperature of the processing vessel 4.

When a film crack occurs in the unnecessary film, an elastic wave occurs. The elastic wave is transmitted from the processing vessel 4 via the waveguide member 46 attached to the flange 8 to the film crack detection apparatus 40 and is finally detected by the elastic wave detection unit 42. The elastic wave detection unit 42 is, for example, the AE sensor 43 including a piezoelectric element. The detection signal is inputted to the determination unit 44 after passing the strength filter 61 through the signal line 56. The strength filter 61 only outputs signals having a strength equal to or greater than the predetermined strength as the elastic wave detection signal S1 in order to cut the noise. Herein, the strength filter 61 is configured to only pass signals having a strength equal to or greater than, for example, 40 dB, while cutting signals having a strength smaller than 40 dB.

In the determination unit 44, the counter 58 counts “one” when one elastic wave detection signal S1 with a sharp needle end shape is inputted, to thereby obtain a cumulative value by adding “one” to the cumulative value after the cleaning process. The cumulative value is sent to the comparator 60. The cumulative value of the counter 58 is reset after every completion of the cleaning process of the processing vessel 4.

The comparator 60 compares the cumulative value with the reference value previously determined for the cumulative value, for example, “100.” However, the reference value “100” is used only for an exemplary purpose in this description and the present disclosure is not limited thereto. If the cumulative value inputted from the counter 58 in the previous step is equal to or greater than the reference value, the comparator 60 determines that there is a need for the cleaning process. The result is displayed on the display unit 45 to call the attention of the operator. In this case, even if the determination is that there is a need for the cleaning process, the film forming process with respect to the currently processed wafers continues to finish without immediately stopping the temperature increasing operation or the film forming process. Therefore, the cleaning process of the processing vessel 4 is performed before starting the next film forming process. As described above, it is possible to detect a film crack of the unnecessary film even during increasing the temperature before the film forming process, the film forming process, and decreasing the temperature after the film forming process to thereby recognize in real time a possibility of the occurrence of particles.

According to the present disclosure, the film crack detection apparatus 40 is mounted to the film forming apparatus 2, which contains the processing vessel 4 for receiving the object to be processed, for example, semiconductor wafers W, and for forming the thin film on the surfaces of the object to be processed, to perform the film crack detection. The film crack detection apparatus 40 includes the elastic wave detection unit 42 mounted to the film forming apparatus 2 to detect the elastic wave, and the determination unit 44 to determine whether the cleaning process of the processing vessel 4 is necessary based on the detection result of the elastic wave detection unit 42. Therefore, it is possible to recognize the possibility of the occurrence of particles in real time by detecting a film crack of the unnecessary film adhered to the inner wall of the processing vessel 4.

### <Modification of Counting>

Next, a modification of counting the number of occurrences of film cracks in the counter 58 will be described. Although the aforementioned first counter is configured to obtain the cumulative value of the number of occurrences of the film cracks occurring after the previous cleaning process, the first counter is not limited thereto and may be configured as provided below.

As a second type of counter, the counter 58 may use a cumulative value of a value measured for a unit time, wherein the measurement is made intermittently. Specifically, instead of continuously performing the operation of detecting a film crack, the film crack detection operation is conducted only for a predetermined unit time, e.g., one second, for example, in every increment of one minute. Then, the operation is repeated. Thereafter, the number of detections by the film crack detection operation for one second is cumulatively added. That is, it is possible to perform the film crack detection operation only for one second of every one minute.

In this case, the reference value as the threshold value in the comparator 60 becomes a value corresponding to the cumulative value obtained during the intermittent measurements, and may be set to, for example, 10 times, which is lower than the reference value for the cumulative value in the previous embodiment, i.e., 100 times. In this case, it is also possible to obtain the same operational effect as the aforementioned first type of counter.

As a third type of counter, the counter 58 may obtain the number of times of the detection of the elastic wave detection signal for every unit time. For example, the film crack detection operation may be continuously performed and may obtain the number of occurrences of the film cracks counted for every unit time, e.g., one second, thereby repeatedly outputting the counted value for every one second. In this case, the reference value as the threshold value in the comparator 60 becomes a value corresponding to the counted value for the unit time and may be set to, for example, 2 times, which is lower than the reference value for the aforementioned second type counter, e.g., 10 times. In this case, it is also possible to obtain the same operational effect as the aforementioned first type of counter.

As a fourth type of counter, the counter 58 may measure the number of times of the detection of the elastic wave detection signal for every unit time and find the tendency of an increase in the number of the detections per the unit time at the same time. For example, since the number of the occurrences of the film cracks rapidly increases in the shape of a quadratic curve as it nears the time for the next cleaning process, the counter 58 may be configured to detect the rapid increase. Specifically, for example, the film crack detection operation is continuously performed and the number of the occurrences of the film cracks is counted for every unit time, e.g., 60 seconds, thereby obtaining the counted value for every 60 seconds. Further, the counter 58 is configured to compare the counted value with the counted value for the immediately prior 60 seconds, thereby outputting an increase rate of the counted value. For example, if the counted value for the immediately prior 60 seconds is 5 times and the counted value for current 60 seconds is 10 times, then the increase rate is 200%, which will be outputted.

The reference value as the threshold value in the comparator 60 becomes a value corresponding to the increase rate and may be set to, for example, 200%. That is, if the increase rate of the film crack occurrences becomes equal to or greater than 200%, the comparator 60 determines that there is a need for the cleaning process. Herein, 60 seconds as the unit time and 200% as the reference value are described for exemplary purposes, and the present disclosure is not limited thereto. In this case, it is also possible to obtain the same operational effect as the aforementioned first type of counter.

### First Modified Embodiment

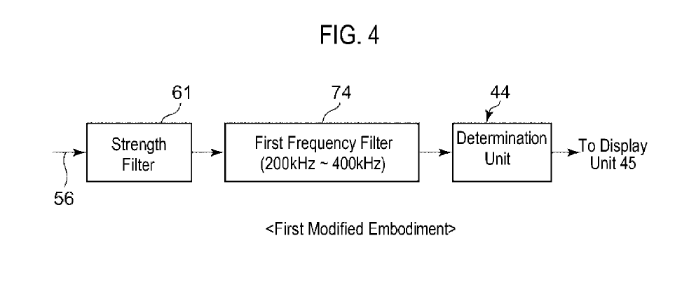

Next, a first modified embodiment of the film crack detection apparatus 40 according to the present disclosure will be described. In the aforementioned embodiment, although the strength filter 61 for cutting the noise is disposed between the elastic wave detection unit 42 and the determination unit 44, it is possible to dispose a first frequency filter for narrowing a frequency band in order to cut the noise more definitely. FIG. 4 shows a portion of the first modified embodiment of the film crack detection apparatus 40 according to present disclosure. The same reference numerals will be assigned to the same elements as the elements shown in FIGS. 1 to 3 and an explanation thereof will be omitted.

As shown in FIG. 4, a first frequency filter 74, which cuts the signals of a predetermined frequency band from the signals outputted from the strength filter 61, is disposed in the signal line 56 between the strength filter 61 and the determination unit 44. A band pass filter, which cuts, for example, a frequency band lower than 200 kHz and a frequency band higher than 400 kHz in order to only pass the frequency bands of between 200 kHz to 400 kHz, may be used as the first frequency filter 74. As described below, since the elastic wave accompanied by the occurrence of a film crack includes a signal showing a sharp needle end shape in the frequency band of about 300 kHz, the detection of these signals may improve the accuracy of detection.

### <Verification Test of Film Crack Occurrence>

Next, since a verification test of the film crack occurrence has actually been performed, a result measured therefrom will be described. Here, two quartz tubes having an outer diameter of 15 mm, an inner diameter of 12 mm, and a length of 1400 mm were prepared as a test material. The entire inner and outer surfaces of one of the two quartz tubes were coated with the silicon nitride film (SiN) in a sufficient thickness (3 μm). The other of two quartz tubes was used as is without coating of any film.

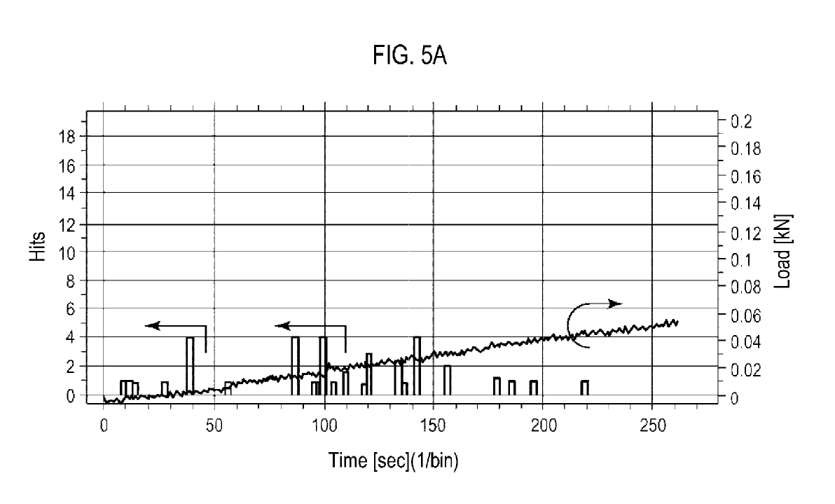

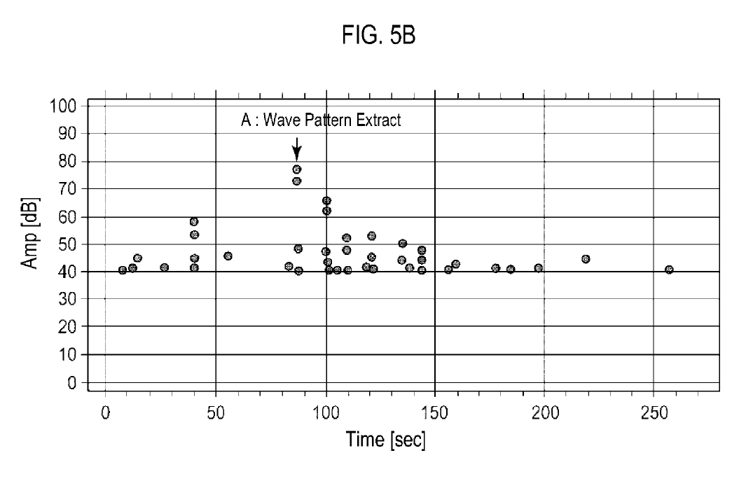

While a load was gradually applied to the center of the quartz tubes in a vertical direction in a state where both ends of the quartz tubes were fixed, being horizontally supported, the elastic wave occurring therefrom was detected by the AE sensor. FIGS. 5A and 5B are graphs showing the relationships between the load and the film crack occurrence. FIG. 5A shows a relationship between the load applied to the quartz tubes and the number of occurrences of the film cracks (Hits: the number of hits), wherein the horizontal axis indicates the time, the right vertical axis indicates the load, and the left vertical axis indicating the number of occurrences of the film cracks (Hits). In FIG. 5B, the horizontal axis indicates the time, and the vertical axis indicates the strength of the signal (Amp). Herein, the filter (corresponding to the strength filter 61 in FIG. 1) cuts signals lower than 40 dB to exclude the noise signal.

The load ranging from 0 to 0.05 kN was applied to the two quartz tubes for about 260 seconds in a manner to linearly increase the load. In the quartz tube without the silicon nitride film coating, the number of hits was not shown to become “zero” until the quartz tube fractured.

On the contrary, in the quartz tube with the silicon nitride film coating, as shown in FIG. 5A, the film cracks begin to occur at a time the load becomes about 0.01 kN. The film cracks occur sporadically as the load increases. The number of occurrences of the film cracks is counted to a maximum of 4 times at the times of 40 sec, 85 sec, 100 sec, and 140 sec in the horizontal axis, respectively.

FIG. 5B shows the strength (dB) of the elastic wave when the number of occurrences of the film cracks is detected in FIG. 5A. Each point in the graph represents the occurrence of a film crack. According to this graph, it can be seen that the strength of the elastic wave at 90 sec (at around 0.015 kN) in the horizontal axis is the greatest. It can be seen from the graphs that the occurrence of the film cracks can be found by detecting the elastic wave.

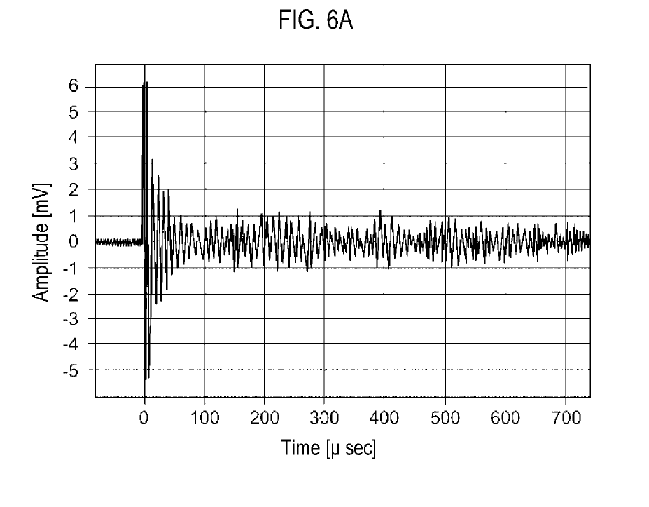

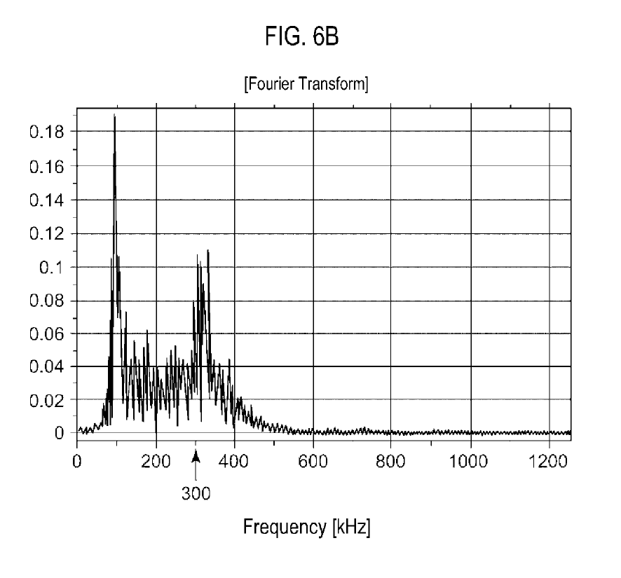

Next, a wave pattern of the elastic wave at a point A where the signal strength of the elastic wave is the greatest in FIG. 5B has been extracted and analyzed. The results are shown in FIGS. 6A and 6B. FIGS. 6A and 6B show the wave patterns at the point where the strength of the elastic wave is the greatest. FIG. 6A shows the amplitude, while FIG. 6B shows the frequency distribution obtained by the Fourier Transform of the signal in FIG. 6A. As shown in FIG. 6A, the detected elastic wave indicates the signal of a large needle end shape having a significantly sharp amplitude in a width of a few μs. Thereafter, the wave pattern of a low amplitude continues for about 700 μs.

In analyzing the frequency of the wave pattern at that time, the sharp peak wave patterns appear at positions near 100 kHz and 300 kHz. Similarly, the two peak wave patterns appear in the detection signals of other elastic waves, although not shown. Therefore, it would be understandable that it is preferable to detect the peak wave pattern having a high frequency of about 300 kHz, cutting the peak wave pattern having a low frequency of about 100 kHz, in order to ensure the exclusion of noise. To this end, the first modified embodiment previously shown in FIG. 4 is configured to use the first frequency filter 74 which only passes signals ranging from 200 kHz to 400 kHz to thereby detect the peak wave patterns near 300 kHz.

### Second Modified Embodiment

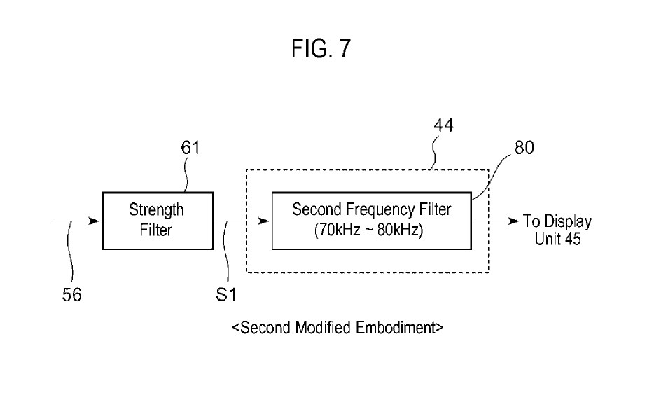

Next, a second modified embodiment of the film crack detection apparatus 40 according to the present disclosure will be described. In the aforementioned embodiments, although the determination unit 44 is configured to include the counter 58 and the comparator 60, it may be possible to use a second frequency filter which determines whether the output of the strength filter 61 has signals of a particular frequency band. FIG. 7 is a partial block diagram showing a second modified embodiment of the film crack detection apparatus 40 according to the present disclosure. In FIG. 7, the same reference numerals will be assigned to the same elements as the elements shown in FIGS. 1 to 6 and an explanation thereof will be omitted.

Herein, a second frequency filter 80 which only passes signals of a particular frequency band is provided as the determination unit 44. It is possible to use a band pass filter as the second frequency filter 80, which passes a signal of the frequency band of, for example, 70 kHz to 80 kHz while cutting signals of other frequencies. The signal having the frequency band of 70 kHz to 80 kHz is an elastic wave occurring when a micro crack arises in the surface of the processing vessel 4 made of quartz or the quartz tube as described below. It is known that if a micro crack occurs, a film crack inevitably occurs in the unnecessary film accumulated on the surface of the processing vessel 4 made of quartz or the quartz tube. Thus, when the micro crack occurs in the quartz surface, it is determined that there is a need for the cleaning process, on the assumption that occurrences of the film cracks occur in great quantities.

The second modified embodiment can be used instead of the embodiments described in FIGS. 1 to 6 or can be used in parallel with them by bifurcating the signal line 56.

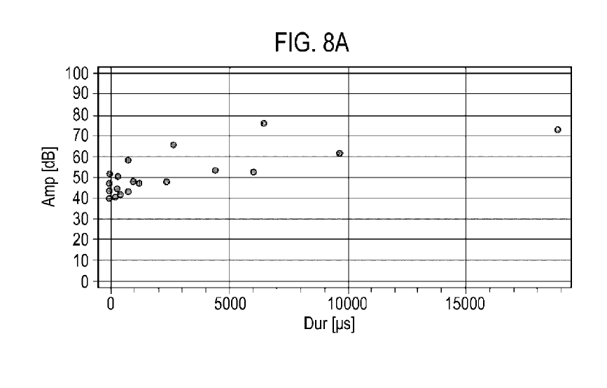

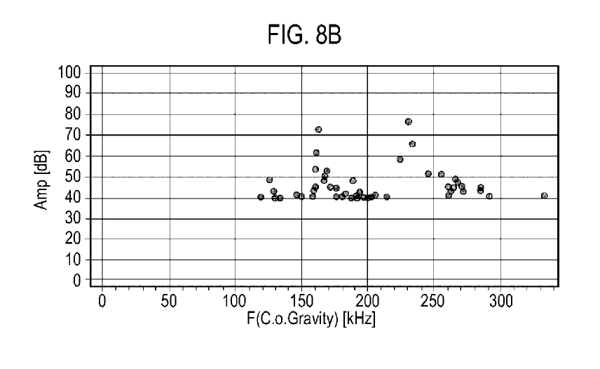

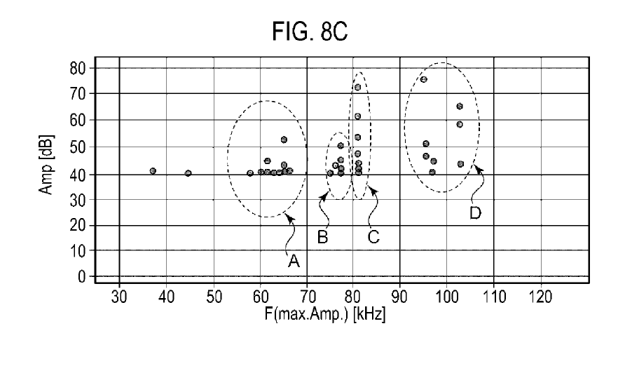

Herein, since an analysis of an elastic wave signal when a micro crack occurs was performed, the analyzed results will be described. FIGS. 8A to 8C are graphs showing an analysis of the occurrence of micro cracks, which are obtained based on the data shown in FIGS. 5A and 5B. FIG. 8A is a graph showing a relationship between a maximum amplitude (Amp) and a wave pattern duration (Dur). FIG. 8B is a graph showing a relationship between a maximum amplitude (Amp) and a center of gravity frequency (F). FIG. 8C is a graph showing a relationship between a maximum amplitude (Amp) and a peak frequency (F). Herein, the wave pattern duration indicates a time during which an envelope curve of the AE wave pattern (the elastic wave) is maintained equal to or greater than a predetermined value. The center of gravity frequency refers to a frequency at a position at the center of gravity of an integrated value of a function obtained from the frequency analysis and is given as follows:

Center of Gravity frequency (kHz)=ΣEi·Fi/ΣEi,

where Ei is a magnitude of a frequency component and Fi is a frequency.

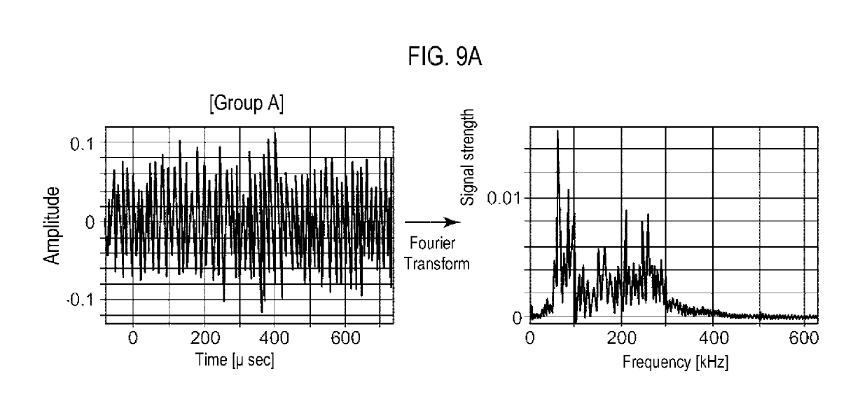

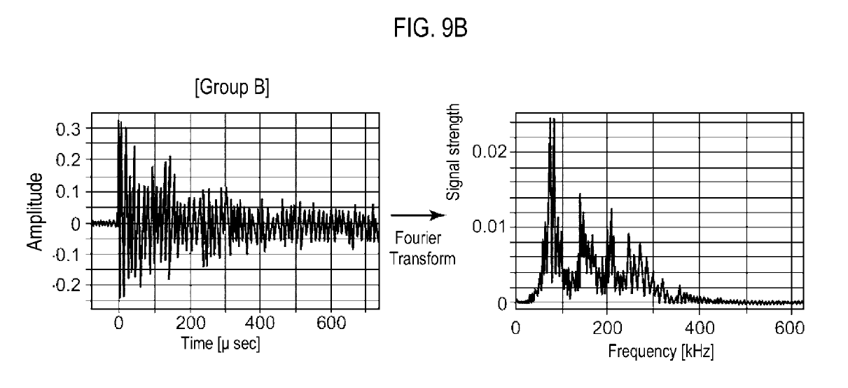

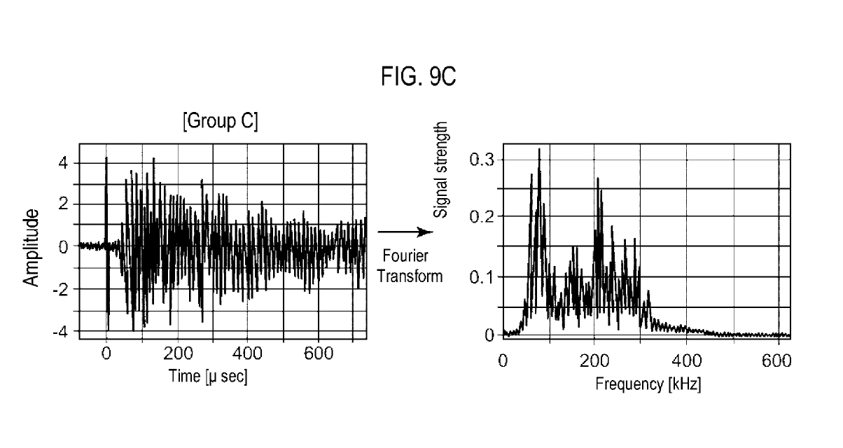

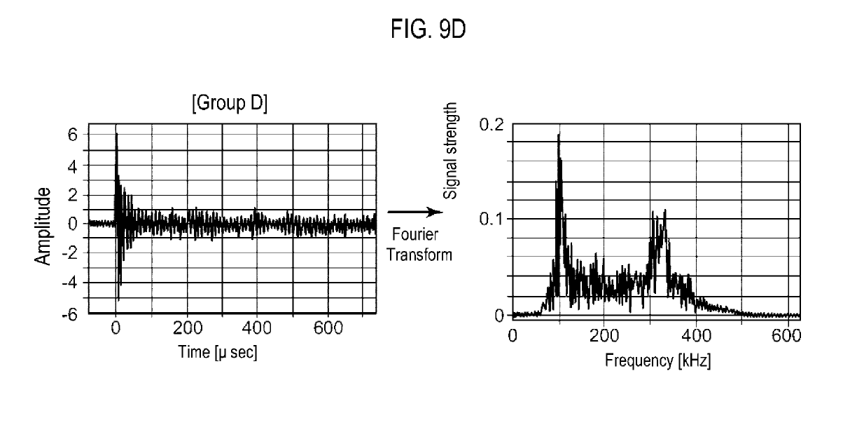

From reviewing the correlation between what is shown in FIGS. 8A and 8B, it is confirmed that classification into four groups of A to D is possible, as shown in FIG. 8C. Specifically, the classification into the groups is made by analyzing the detected AE original form waves, with consideration of a magnitude of the amplitude, the wave pattern duration and the frequency analysis, as shown in FIGS. 8A to 8C. FIGS. 9A to 9D are graphs showing the relationships between the AE original form wave and the frequency distribution by groups. FIG. 9A shows “Group A,” FIG. 9B shows “Group B,” FIG. 9C shows “Group C,” and FIG. 9D shows “Group D.” In the graphs on the left side, the horizontal axis indicates the time, and the vertical axis indicates the amplitude. In the graphs on the right side, the horizontal axis indicates a frequency obtained by a Fourier Transform, and the vertical axis indicates the signal strength.

By observing the wave patterns of the AE original form waves (the elastic waves) of the groups, it can be confirmed that the features of the wave patterns are different from one another, as shown in FIGS. 9A to 9D. The difference in the wave patterns is thought to result from the differences in an occurrence mechanism of the AE original form wave. Thus, classification into four groups of A to D as shown below is possible from the determination based on the occurrence frequency and the timing.

Group A: Occurrence and growth of a micro crack in SiN Film

Group B: Occurrence and Development of a micro crack in quartz glass

Group C: Unknown Phenomenon

Group D: Unknown Phenomenon

Here, it is confirmed that the elastic wave belonging to Group B in FIG. 8C occurs when a micro crack occurs in the surface of the quartz to thereby cause the occurrence of the film crack. It is possible to find the micro crack occurring in the surface of the quartz and the film crack occurrence accompanying the micro crack by detecting the elastic wave with the frequency band belonging to Group B, for example, 70 kHz to 80 kHz, as described in FIG. 7.

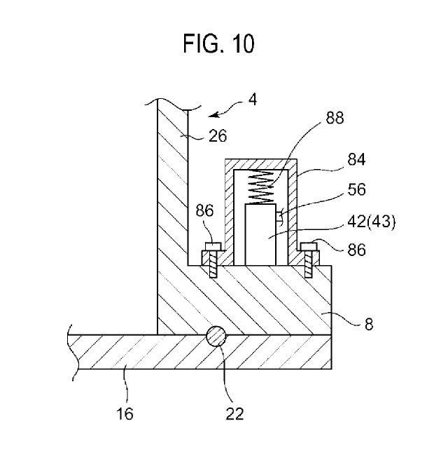

In the above embodiments, although a case where the elastic wave detection unit 42 is connected to the flange 8 via the waveguide member 46 is described as an example, it is possible to mount the elastic wave detection unit 42 as shown in a modified embodiment of the elastic wave detection unit in FIG. 10. In FIG. 10, the reference numerals will be assigned to the same elements as the elements shown in FIG. 2. Herein, the elastic wave detection unit 42 is received in a sensor receiving case 84 having an opening at one end and fixed to the surface of the flange 8 by bolts 86 at its opening end. The sensor receiving case 84 also receives a spring member 88 therein, wherein the spring member 88 serves to press the elastic wave detection unit 42 from a rear side toward the flange 8 to thereby allow a front end of the elastic wave detection unit 42 to be in close contact with the surface of the flange 8. In this case, it may be also possible to interpose the close-contact members 54 between the elastic wave detection unit 42 and the flange 8.

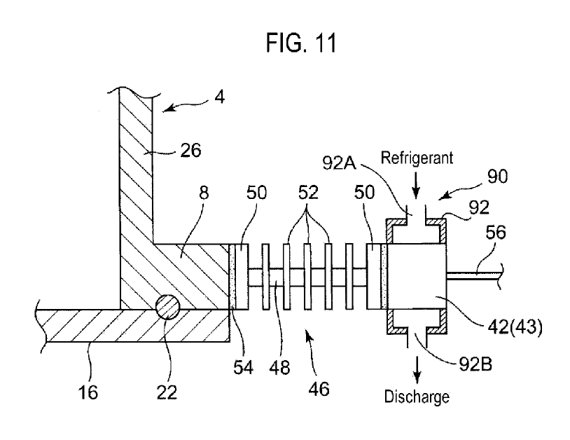

Further, in another modified embodiment of the elastic wave detection unit shown in FIG. 11, the elastic wave detection unit 42 may be provided with a cooling device 90 so as to cool the elastic wave detection unit 42. In FIG. 11, the same reference numerals will be assigned to the same elements as shown in FIG. 2. The cooling device 90 has a cooling case 92 mounted to surround the elastic wave detection unit 42. The cooling case 92 is provided with a refrigerant inlet 92A and a refrigerant outlet 92B therein to cool the elastic wave detection unit 42 by flowing a refrigerant through the cooling case 92. In the description above, it is possible to prevent the elastic wave detection unit 42 from being destroyed by heat by cooling the elastic wave detection unit 42. Herein, it is possible to use a cooling gas such as nitrogen gas or a cooling liquid such as cooling water as the refrigerant.

In addition, it is possible to mount the elastic wave detection unit 42 to any portion of the processing vessel 4. Further, in the case that a manifold is provided at the lower end portion of the processing vessel 4, the elastic wave detection unit 42 may be mounted to the manifold. Although the forming of the silicon nitride film is exemplified in these embodiments, the present disclosure is not limited thereto and can be applied in forming any kind of thin film. Further, although the batch type film forming apparatus is described as an example, the present disclosure is not limited thereto and can be applied to a film forming apparatus of a type of a so-called single wafer processing apparatus in which the semiconductor wafers are processed one by one.

Further, although the semiconductor wafer is exemplified as the processed object, the semiconductor wafer may include a silicon substrate or a compound semiconductor substrate such as GaAs, SiC, GaN, etc. Further, the present disclosure is not limited to these substrates and can be applied to a glass substrate or a ceramic substrate used in a liquid crystal display.

According to the present disclosure, the film crack detection apparatus is mounted to a film forming apparatus to perform a film crack detection operation, the film forming apparatus having a processing vessel for receiving an object to be processed and forming a thin film on a surface of the object to be processed. The film crack detection apparatus has an elastic wave detection unit mounted to the film forming apparatus to detect an elastic wave, and a determination unit to determine whether a cleaning process of the processing vessel is necessary based on a detection result of the elastic wave detection unit. Therefore, it is possible to recognize a possibility of particle occurrence in real time by detecting a film crack of an unnecessary film attached on an inner wall of a processing vessel.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The various embodiments are not necessarily mutually exclusive as aspects of one embodiment can be combined with aspects of another embodiment. The accompanying claims and their equivalents are intended to cover such forms or modifications as would fall within the scope and spirit of the disclosures.

What is claimed is:

1. A film crack detection apparatus, mounted to a film forming apparatus, for performing a film crack detection operation, the film forming apparatus having a processing vessel for receiving an object to be processed and forming a thin film on a surface of the object to be processed, comprising:
an elastic wave detection unit mounted to the film forming apparatus to detect an elastic wave; and
a determination unit to determine whether performing a cleaning process of the processing vessel is necessary based on a detection result of the elastic wave detection unit.

2. The film crack detection apparatus of claim 1, further comprising a strength filter outputting signals having a strength equal to or greater than a predetermined strength as elastic wave detection signals among signals outputted from the elastic wave detection unit.

3. The film crack detection apparatus of claim 2, further comprising a first frequency filter passing signals of a predetermined frequency band among signals outputted from the strength filter.

4. The film crack detection apparatus of claim 2, wherein the determination unit comprises:
a counter obtaining a number of detections of the elastic wave detection signals; and
a comparator comparing an output of the counter with a predetermined reference value.

5. The film crack detection apparatus of claim 4, wherein the counter is configured to obtain a cumulative value after a previous cleaning process of the processing vessel.

6. The film crack detection apparatus of claim 4, wherein the counter is configured to obtain a cumulative value of the number of detections measured for a unit time, the measurement being made intermittently.

7. The film crack detection apparatus of claim 4, wherein the counter is configured to obtain the number of detections of the elastic wave detection signal for every unit time.

8. The film crack detection apparatus of claim 4, wherein the counter is configured to obtain the number of detections of the elastic wave detection signal for every unit time and an increase tendency of the number of detections per the unit time at the same time.

9. The film crack detection apparatus of claim 2, wherein the determination unit includes a second frequency filter to determine whether the signals outputted from the strength filter has a signal of a particular frequency band.

10. The film crack detection apparatus of claim 1, wherein the film crack detection operation is performed during increasing a temperature of the processing vessel, during decreasing a temperature of the processing vessel, and during forming the thin film.

11. The film crack detection apparatus of claim 1, further comprising a display unit displaying a determination result of the determination unit.

12. The film crack detection apparatus of claim 1, wherein the elastic wave detection unit is provided with a cooling device to cool the elastic wave detection unit.

13. A film forming apparatus for forming a thin film on an object to be processed, comprising:
a processing vessel to receive the object to be processed;
a holding device to hold the object to be processed;
a heater to heat the object to be processed;
a gas supply unit to supply a gas into the processing vessel;
an exhaust system to exhaust an atmosphere within the processing vessel;
the film crack detection apparatus of claim 1; and
a controller to control the entire operation of the film forming apparatus.

14. The film forming apparatus of claim 13, wherein the film crack detection apparatus is mounted to the processing vessel.

15. The film forming apparatus of claim 13, wherein the film crack detection apparatus is mounted to a manifold installed at a lower portion of the processing vessel.

16. The film forming apparatus of claim 14, wherein the film crack detection apparatus is mounted via a metallic waveguide member.

17. The film forming apparatus of claim 16, wherein the waveguide member is provided with radiating fins.
